(19) United States
(12) Patent Application Publication
(10) Pub. No.: US 2004/0143781 A1
(43) Pub. Date: Jul. 22, 2004

(54) System and method for non-intrusive loopback testing

(76) Inventors: Francesco DiMambro, San Jose, CA (US); Hongping Yuan, San Jose, CA (US)

Correspondence Address: PARK, VAUGHAN & FLEMING LLP, 702 MARSHALL STREET, SUITE 310, REDWOOD CITY, CA, 94063, US

(21) Appl. No.: 10/348,744

(22) Filed: Jan. 21, 2003

(51) Int. Cl. G01R 31/28

(52) U.S. Cl. 714/716

(57) ABSTRACT

A system and method for performing non-intrusive loopback testing in a communication device. When a loopback mode of testing is requested for the communication device (e.g., from a diagnostic application), and one or more communication streams are active or bound to the device, the streams are suspended instead of terminated. In a list of the active streams, maintained in the device's information data structure, a device driver or the application modifies each of the streams (e.g., by setting a flag). While a stream is suspended, any traffic for the stream is dropped. After the loopback testing is completed, the streams are reactivated.

### BACKGROUND

This invention relates to the field of computer systems. More particularly, a system and method are provided for performing loopback testing in a communication device in a non-intrusive manner.

Many communication devices, such as NICs (Network Interface Cards), are able to perform some type of loopback testing to test the device's transmit and receive components or modules. Loopback testing typically involves the routing of predetermined communications (e.g., test patterns) between transmit and receive components. Such testing can determine whether the components are working correctly, without actually attempting to transmit across a network or other external communication link.

Diagnostic tools (e.g., applications or utilities) operating on a computer system may interact with a communication device or interface, or a corresponding device driver, in order to initiate loopback testing. However, current diagnostic tools must have some information regarding a device's loopback testing capabilities before they can invoke those capabilities. A device's loopback capabilities may indicate the locations, modules or protocol layers within the device at which loopback testing can be performed.

In some systems, a diagnostic tool and a communication device's driver may be designed or compiled with identifications of the device's loopback capabilities. In particular, one or more constants may be defined and shared between a tool and a device driver (e.g., in header files used by both programs), to represent individual loopback testing capabilities.

Unfortunately, such tools comprise static definitions of a device's loopback capabilities. As a result, in order to perform loopback testing on a particular communication device, a diagnostic tool specifically configured for the device must be used.

If the capabilities of a device change, or the device is replaced with one having different capabilities, the tool must be replaced or recompiled. Thus, every time a communication device or its loopback testing capabilities are upgraded, a diagnostic tool for initiating loopback testing on the device must be altered or replaced as well.

Also, when a communication device is operating in a loopback mode, other communication streams cannot use the device. In some systems, such streams are abruptly terminated when loopback mode is initiated, or a loopback test cannot be initiated until the streams are terminated. Considering the relatively short duration of a loopback test (e.g., could be less than one second), terminating other communication streams may seem severe.

### SUMMARY

In one embodiment of the invention, a system and method are provided for performing loopback testing in a communication device in a non-intrusive manner. When a loopback mode of testing is requested for the communication device (e.g., from a diagnostic application), and one or more communication streams are active or bound to the device, the streams are suspended instead of terminated. In a list of the active streams, maintained in the device's information data structure, a device driver or the application modifies each of the streams (e.g., by setting a flag). While a stream is suspended, any traffic for the stream is dropped. After the loopback testing is completed, the streams are reactivated.

In this embodiment, an application corresponding to a suspended stream continues to execute. Because of the typically short duration of loopback testing, any communications that were dropped while the stream was suspended can be quickly recovered.

### DESCRIPTION OF THE FIGURES

FIG. 1 is a block diagram depicting a communication device whose loopback capabilities may be queried, in accordance with an embodiment of the present invention.

FIG. 2 is a flowchart illustrating one method by which a diagnostic application may determine the loopback capabilities of a communication device, in accordance with an embodiment of the invention.

FIGS. 3A-B depict a communication device and device driver for applying a non-intrusive method of loopback testing, in accordance with an embodiment of the present invention.

FIG. 4 is a flowchart illustrating one method by which a non-intrusive method of loopback testing may be applied to a communication device, in accordance with an embodiment of the invention.

### DETAILED DESCRIPTION

The following description is presented to enable any person skilled in the art to make and use the invention, and is provided in the context of particular applications of the invention and their requirements. Various modifications to the disclosed embodiments will be readily apparent to those skilled in the art and the general principles defined herein may be applied to other embodiments and applications without departing from the scope of the present invention. Thus, the present invention is not intended to be limited to the embodiments shown, but is to be accorded the widest scope consistent with the principles and features disclosed herein.

The program environment in which a present embodiment of the invention is executed illustratively incorporates a general-purpose computer or a special purpose device such as a hand-held computer. Details of such devices (e.g., processor, memory, data storage, display) may be omitted for the sake of clarity.

It should also be understood that the techniques of the present invention may be implemented using a variety of technologies. For example, the methods described herein may be implemented in software executing on a computer system, or implemented in hardware utilizing either a combination of microprocessors or other specially designed application specific integrated circuits, programmable logic devices, or various combinations thereof. In particular, the methods described herein may be implemented by a series of computer-executable instructions residing on a suitable computer-readable medium. Suitable computer-readable media may include volatile (e.g., RAM) and/or non-volatile (e.g., ROM, disk) memory, carrier waves and transmission media (e.g., copper wire, coaxial cable, fiber optic media). Exemplary carrier waves may take the form of electrical, electromagnetic or optical signals conveying digital data streams along a local network, a publicly accessible network such as the Internet or some other communication link.

In an embodiment of the invention, an apparatus and method are provided to allow a communication device's loopback testing capability to be determined by an application (e.g., a diagnostic tool or utility). The device may comprise a communication interface or adapter, such as a NIC (Network Interface Card), or another device capable of electronically transmitting and receiving electronic signals. In this embodiment, the application queries the device (or an associated device driver) and receives information regarding the device's capabilities.

In another embodiment of the invention, a system and method of non-intrusive loopback testing are provided. In this embodiment, a communication device or device driver blocks or suspends other communication streams, rather than terminating them, when a loopback test or loopback mode of operation is initiated.

Determining a Communication Device's Loopback Capabilities

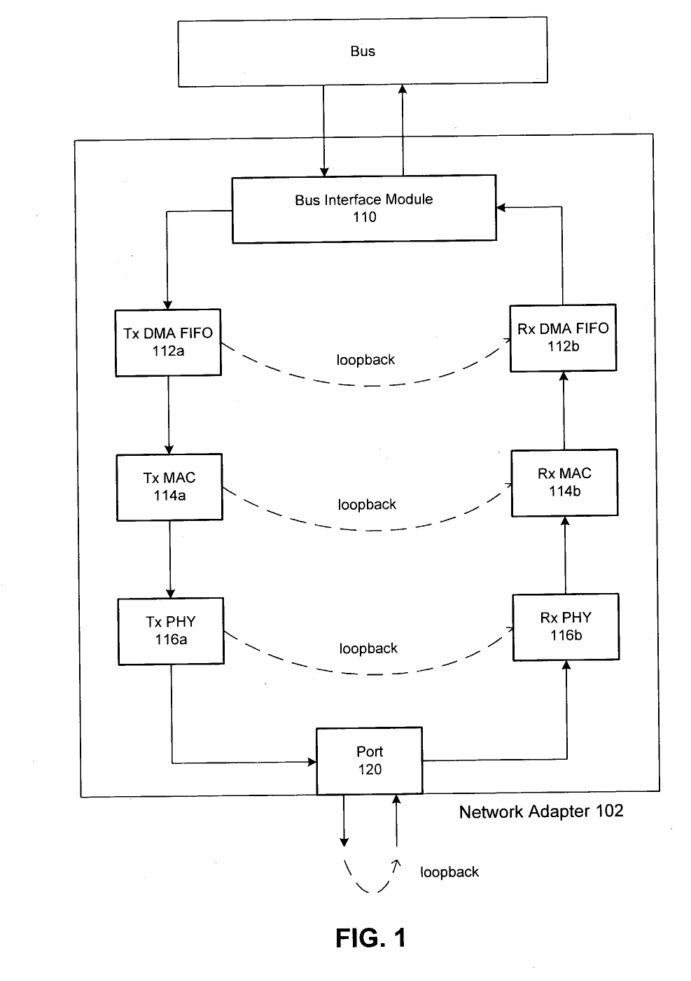

FIG. 1 depicts a communication device for which an embodiment of the invention may be implemented. In FIG. 1, adapter 102 is a NIC or other communication interface device configured for network (e.g., Ethernet) communications. In other embodiments of the invention, a communication device may be of virtually any type and may be configured for any communication format or protocol (e.g., USB (Universal Serial Bus), IEEE 1394, InfiniBand).

Adapter 102 includes Bus Interface Module (BIM) 110, which is coupled to a bus (e.g., PCI, ISA) of a computer system. The bus couples the adapter to a processor configured to execute a device driver (not shown) for operating adapter 102, a diagnostic application for testing the adapter, and other programs. Port 120 allows the adapter to be coupled to a suitable communication link (e.g., copper, fiber) for communicating with another entity (e.g., a switch, a router, another computer system). A loopback plug may be connected to port 120.

Adapter 102 also includes DMA (Direct Memory Access) modules or components for transmitting (element 112a) and receiving (element 112b) signals. The DMA modules facilitate movement of data between the network adapter and other components of the computer system (e.g., a processor, memory). The adapter also includes transmit and receive MAC (Medium Access Control) modules 114a, 114b and PHY (physical layer) modules 116a, 116b. The various modules of adapter 102 may be located on different chips or ASICs (Application-Specific Integrated Circuit), or multiple modules may be colocated on a chip.

In the illustrated embodiment of the invention, the DMA modules, MAC modules and PHY modules, and the port, represent different loopback capabilities. In this embodiment, a loopback capability refers to a location or point within adapter 102, or a layer of a protocol stack applied to adapter 102, at which loopback testing may be performed. In other embodiments of the invention, a communication device may have any number of loopback capabilities, and may not directly match the capabilities depicted in FIG. 1. For example, communication devices configured for different communication formats may employ different types of components or modules for routing transmit and receive traffic, some or all of which may have loopback abilities. Virtually any communication device capable of transmitting and receiving electronic signals may be able to implement an embodiment of the invention.

At each point of loopback capability within adapter 102, transmit traffic can be routed to the receive flow of traffic, as indicated by the dashed lines in FIG. 1. Thus, by exercising different loopback capabilities, different layers or modules of the adapter can be tested for correct operation.

In addition to the various locations or layers at which loopback testing may be performed, different data rates may also be tested. Thus, each loopback capability of adapter 102 (e.g., DMA, MAC, PHY, external port) may be tested at multiple speeds (e.g., 10 Mbps, 100 Mbps, 1000 Mbps, 10000 Mbps).

In an embodiment of the invention, a request to identify a communication device's loopback capabilities is received from an application, such as a diagnostic tool. The request is received by a device driver corresponding to the device. The driver responds by transmitting to the application a set of information identifying the device's loopback capabilities. The loopback capability information may be stored in a memory of the computer system, may be maintained in a device information data structure controlled by the device driver, or may be generated or assembled in response to a request.

Illustratively, a loopback capability data structure may include entries for one or more loopback testing capabilities. An entry for a loopback capability may include a type of capability (e.g., internal, external), a character string (e.g., a label or key) describing the capability (e.g., “MAC loopback at 100 Mbps”), a shorter identifier (e.g., a numeric constant), etc. The descriptive string may be used by the application to identify the loopback testing capability (e.g., to offer choices of different tests to a user, to record which test was run). The shorter identifier may be used by the application to identify to the device driver a loopback capability to be exercised.

A communication interface protocol may be defined for use by a communication device's driver and an application wanting to exercise one or more of the device's loopback capabilities. For example, the protocol may specify how the application queries the device driver to obtain the device's loopback capabilities, how the driver identifies the capabilities to the application, how the application selects and identifies a loopback capability to be tested, etc. Or, an existing protocol may be applied (e.g., DLPI—Data Link Protocol Interface).

In one embodiment of the invention, a communication device's driver maintains one or more data structures other than a loopback capability data structure. For example, the driver may maintain a per-stream data structure to represent each stream of traffic passing through the device.

In this embodiment, each stream's structure includes an identifier of the stream's current status. One of the possible statuses may indicate that the stream is in a loopback mode. When a stream is in loopback mode, its outgoing packets are not actually transmitted over an external communication link. Because of the nature of loopback testing, the device may be limited to having only one stream at a time in a loopback mode. Also, other streams through the device may be blocked or suspended while a stream is in loopback mode, until the loopback testing is completed.

In one embodiment of the invention, a driver for a communication adapter and a program (e.g., an application, a utility) configured to perform loopback testing on the adapter include the following common structures:

typedef uint32_t lb_info_sz_t; /* Size of loopback cap. structure */

| | |
|---|---|
| typedef enum { | |
| normal, | /* Normal operation, allows exit out of loopback */ |
| internal | /* Loopback is internal to the adapter or ASIC */ |
| external, | /* Requires a wired loopback connector */ |
| } lb_type_t; | |

In this embodiment, the adapter's loopback capability structure includes three elements filled in by the adapter's driver. Each loopback capability is defined by a different set of values for the three elements. The loopback capability structure may be configured as follows:

typedef struct_lb_property_t {

| | |
|---|---|
| lb_type_t lb_type; | /* Loopback type (e.g., int, ext, normal) */ |
| char key[16]; | /* Description of loopback capability */ |
| uint32_t value; | /* Loopback capability identifier */ |

} lb_property_t, *p_lb_property_t;

In the preceding sample loopback capability structure, the “value” is the loopback capability identifier passed between the driver and the program exercising the adapter's loopback testing. The “key” is intended to provide a human-readable string which can be used by the program to identify (e.g., to a user) which loopback is currently underway.

The definitions below exemplify the variety of loopback capabilities that can be configured for a communication adapter (each enumeration is a possible “value” for the property structure defined above):

```
typedef enum {
    lb_normal,
    lb_ext1000,
    lb_ext100,
    lb_ext10,
    lb_phy,
    lb_serdes,
    lb_mac1000,
    lb_mac
} ce_lb_t;
```

The following code may be used to initialize the property structure:

```
static lb_property_t lb_normal =
    {normal, “normal”, lb_normal};
static lb_property_t lb_external1000 =
    {external, “external1000”, lb_ext1000};
static lb_property_t lb_external100 =
    {external, “external100”, lb_ext100};
static lb_property_t lb_external10 =
    {external, “external10”, lb_ext10};
static lb_property_t lb_phy =
    {internal, “phy”, lb_phy};
static lb_property_t lb_mac1000 =
    {internal, “mac1000”, lb_mac1000};
static lb_property_t lb_mac =
    {internal, “mac10/100”, lb_mac};
```

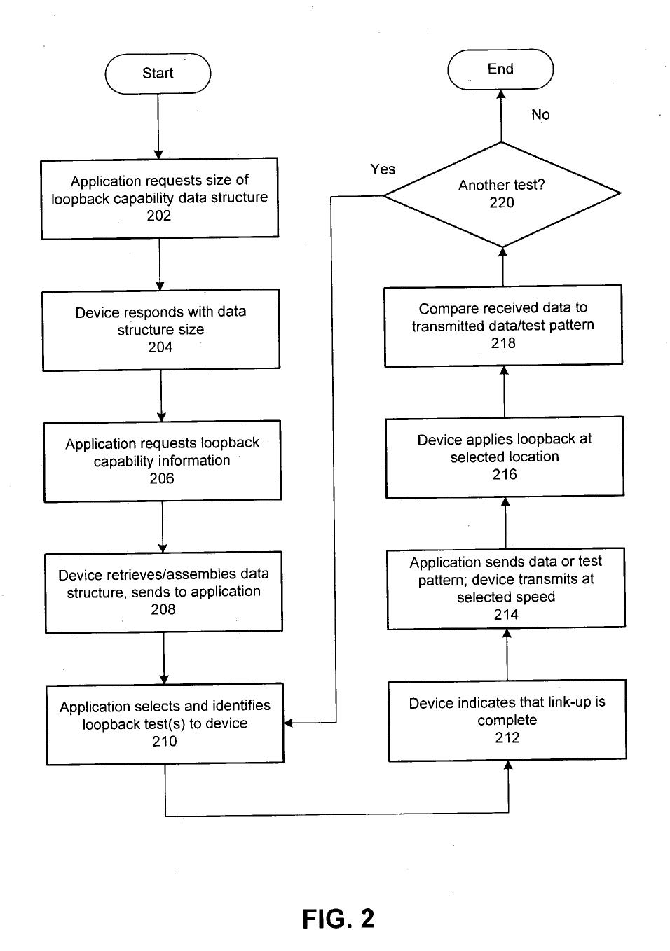

FIG. 2 is a flowchart demonstrating a method of determining a communication device's loopback capabilities, according to one embodiment of the invention. Prior to, or as an initial part of the method depicted in FIG. 2, the communication device is opened by its device driver, the driver is attached to the device, and one or more protocols are bound to the device.

In operation 202, a diagnostic application or tool sends to the device's driver a request for the size of the device's loopback capability data structure. Because the entire structure will be sent to the application, the application needs to know how much memory to allocate to accommodate the structure.

In operation 204, the device driver responds by informing the application of the size of the loopback capability data structure. A loopback capability data structure may be any size, depending on the associated device's loopback capabilities.

In operation 206, the application sends the device driver a message asking for the device's loopback capabilities. In operation 208, the driver responds by sending the device's loopback capability data structure. The data structure may be assembled in response to the request, or may be retrieved from storage.

If the device driver returns an error in operation 204 or operation 208, this may indicate that the driver is not configured to inform the application of the device's loopback capability. In this case, the ability to initiate loopback testing may depend upon whether the application includes any other knowledge of the device's capabilities. If it can pass to the driver an identifier of a capability, the procedure may advance to operation 210.

In operation 210, the application selects one or more loopback capabilities or tests. Illustratively, each selection may identify a particular module in the device, a particular layer of its protocol stack, a speed at which to operate, etc. Thus, one test may request loopback at the MAC layer, at 100 Mbps; another may request loopback at the external port (e.g., using a loopback plug) at 1000 Mbps.

The application informs the device driver of which loopback test (and speed) to exercise, by sending another message to the device. The message may identify the test by a label, tag, constant or string that was included in the loopback capability data structure passed to the application. Illustratively, the application may iteratively select and exercise multiple (e.g., all) loopback capabilities in sequence.

In another embodiment, one or more tests may be identified together, in which case the tests may be automatically applied one after the other. For example, the application may specify that all internal or external capabilities are to be tested. The device driver may then sequence among the corresponding capabilities.

In operation 212, the device driver informs the application that link-up is complete. In particular, the driver notifies the application when it is ready to proceed with the loopback test. As part of the link-up process, the driver may suspend one or more other communication streams in favor of the loopback test, instruct the device to enter loopback mode at a specified module or layer, etc.

The application may specifically query the device driver as to whether link-up is complete, or may wait for a signal from the driver. As yet another alternative, the application may simply wait a period of time (e.g., two seconds) and then proceed to operation 214. In this alternative, only if the transmitted test data are not received correctly will the application examine the link-up status or assume that it failed.

The driver may also take other action in response to the commencement of loopback testing (e.g., drop any communications received from an external communication link, update per-device and/or per-stream data structures to reflect the testing).

In operation 214, the application sends the device driver some data (e.g. a test pattern) for loopback testing. The driver implements its transmission process to send the data at a desired data rate.

In operation 216, the device loops the data from its transmit path to its receive path at the specified location or layer, and forwards the received data to the driver.

In operation 218, the received data are compared to the transmitted data (e.g., by the application). Test results may be aggregated for multiple iterations and/or separate loopback tests. During and/or after the testing is complete, the application may report the results to a user or store them.

In operation 220, if another loopback capability is to be exercised, the illustrated method may return to operation 210 so the application can identify a different capability. As described above, the application (or the device driver) may loop through the different testing capabilities.

Non-Intrusive Loopback Testing

In another embodiment of the invention, a non-intrusive method of loopback testing allows non-loopback streams, such as IP (Internet Protocol), IPv6 (Internet Protocol, version six), ARP (Address Resolution Protocol), a snoop utility, upper layer protocols and so on, to be suspended at the driver level (e.g., instead of being terminated during the loopback testing). While in loopback mode, the connection states of the other communication streams are maintained, thereby allowing them to easily resume when no longer suspended.

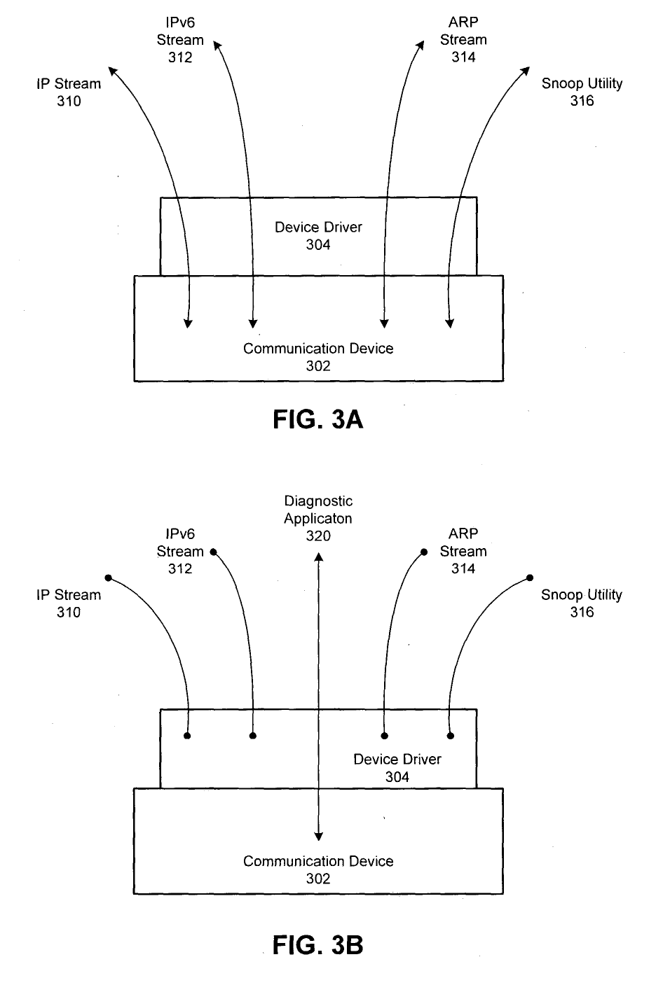

FIG. 3 depicts a system in which one implementation of this embodiment of the invention may be applied. In this implementation, device driver 304 controls or manages operation of communication device 302, which may be a NIC, a channel adapter or other device. Communication device 302 couples a computer system to an external communication link (not shown), to facilitate network traffic and/or other communications. In different embodiments of the invention, a communication device may be configured for virtually any type or format of bi-directional communications (e.g., Ethernet, InfiniBand, IEEE 1394).

In FIG. 3A, multiple communication streams are active through device driver 304 and communication device 302. Thus, IP stream 310 comprises incoming and outgoing IP traffic, and IPv6 stream 312 comprises IPv6 traffic. ARP stream 314 includes address resolution protocol traffic, and snoop utility 316 allows the computer system to observe some or all communications handled by communication device 302.

In FIG. 3B, streams 310, 312, 314 and 316 are suspended or blocked at the device driver, because diagnostic application 320 has initiated a loopback mode of operation for communication device 302. As described in a previous section, a communication device may have multiple loopback capabilities. Therefore, diagnostic application 320 may be exercising one or more of the loopback capabilities of communication device 302.

In this embodiment, while a communication stream is suspended and the communication device is in loopback mode, any outgoing communications for that stream received at device driver 304 or communication device 302 are dropped. Similarly, any incoming communications for the stream received at communication device 302 from an external communication link are rejected or dropped.

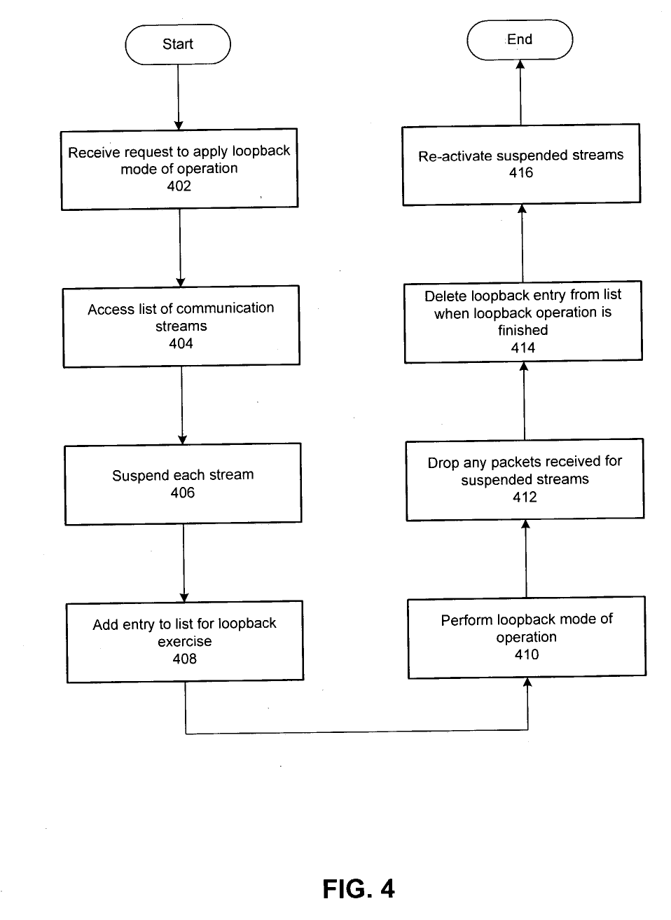

FIG. 4 demonstrates a method of applying non-intrusive loopback testing to a communication device, according to one embodiment of the invention. In this embodiment, communication streams are merely suspended, rather than terminated, while the device is operated in a loopback mode.

In operation 402, a device driver or communication device receives a request to initiate a loopback mode of operation. The request may be received from a diagnostic utility or application. As described above, the application may learn of the device's loopback capabilities by querying the device or device driver. Alternatively, the application may already possess knowledge of such capabilities. Thus, the application may specify a particular type of loopback mode (e.g., at a specific data rate, at a particular location in the communication device, at a specified layer of the communication protocol stack), or may instruct the driver to engage in a series of loopback operations or tests.

In operation 404, the device driver (or the application) accesses a list of communication streams; each active communication stream is represented by an entry in the list. Illustratively, the list may be maintained by the communication device's driver, as part of the communication device's information data structure.

In operation 406, the device driver or the application suspends each stream by updating its entry in the list to indicate a suspended status. This may entail setting (or clearing) a flag or field in the entry. Though suspended, each stream can be easily resumed. While a communication stream is suspended, its corresponding application (e.g., operating in the application layer of the protocol stack) may continue to execute.

In operation 408, an entry representing the requested loopback mode is added to the list of communication streams. This entry is not placed in a suspended status.

In operation 410, the communication device is operated in the desired loopback mode. For example, the driver may instruct the device to activate a loopback capability. While operating in loopback mode, a communication (e.g., a test packet) submitted to the device's transmit flow is conveyed to the device's receive flow at the desired location or layer of the device, instead of being transmitted on an external link. When the communication loops back (e.g., to the driver or application), it is compared to what was sent.

In operation 412, while the device is operated in loopback mode, non-loopback communications received at the device and/or device driver are dropped.

In operation 414, the loopback operation or testing is completed. Therefore, the device is reconfigured for normal operation and the entry in the communication stream list corresponding to the loopback operation may be deleted.

In operation 416, the suspended communication streams are resumed or reactivated, by updating their statuses appropriately in the list of communication streams. Because of the short duration of loopback testing, a stream may be able to quickly correct for any packets or other communications that were dropped or lost during the time the stream was suspended.

The foregoing embodiments of the invention have been presented for purposes of illustration and description only. They are not intended to be exhaustive or to limit the invention to the forms disclosed. Accordingly, the scope of the invention is defined by the appended claims, not the preceding disclosure.

What is claimed is:

1. A method of performing loopback testing, comprising:
receiving a request to initiate loopback testing of a communication device;
identifying one or more communication streams bound to the communication device;
suspending the one or more communication streams without terminating them;
initiating the loopback testing; and
after completion of the loopback testing, resuming the one or more communication streams.

2. The method of claim 1, further comprising, after said suspending:
receiving a communication for a first communication stream; and
dropping the communication.

3. The method of claim 2, wherein the communication is received from a program executing in a computer system comprising the communication device.

4. The method of claim 2, wherein the communication is received from an entity external to a computer system comprising the communication device.

5. The method of claim 2, further comprising prior to said dropping:
identifying the first communication stream; and
determining the status of the first communication stream.

6. The method of claim 1, wherein said receiving, identifying, suspending and resuming are performed by a device driver configured to drive the communication device.

7. The method of claim 1, wherein said identifying comprises:
accessing a device information data structure maintained by a device driver configured to drive the communication device; and
accessing a list of the one or more communication streams.

8. The method of claim 7, wherein said suspending comprises:
within the list, changing a status of each of the one or more communication streams.

9. The method of claim 7, wherein said initiating comprises:
adding the loopback testing to the list.

10. A computer readable storage medium storing instructions that, when executed by a computer, cause the computer to perform a method of performing loopback testing, the method comprising:
receiving a request to initiate loopback testing of a communication device;
identifying one or more communication streams bound to the communication device;
suspending the one or more communication streams without terminating them;
initiating the loopback testing; and
after completion of the loopback testing, resuming the one or more communication streams.

11. A non-intrusive method of loopback testing of a communication device within a computer system, the method comprising:
facilitating one or more communication streams through the communication device, including a first communication stream;
receiving a request to initiate a loopback operation in the communication device;
suspending each of the one or more communication streams;
initiating the loopback operation;
receiving a communication as part of the first communication stream;
dropping the communication; and
resuming each of the one or more communication streams after completion of the loopback operation.

12. The method of claim 11, wherein said suspending comprises:
accessing a device information data structure maintained by a device driver of the communication device; and
setting a status of each of the one or more communication streams in the device information data structure.

13. The method of claim 12, wherein said resuming comprises:
accessing the device information data structure; and
resetting the status of each of the one or more communication streams.

14. A computer readable storage medium storing instructions that, when executed by a computer, cause the computer to perform a non-intrusive method of loopback testing of a communication device within a computer system, the method comprising:
facilitating one or more communication streams through the communication device, including a first communication stream;
receiving a request to initiate a loopback operation in the communication device;
suspending each of the one or more communication streams;
initiating the loopback operation;
receiving a communication as part of the first communication stream;
dropping the communication; and
resuming each of the one or more communication streams after completion of the loopback operation.

15. A computer system, comprising:
a communication device coupleable to an external communication link;
a device driver configured to drive operation of the communication device;
one or more communication streams, wherein each of the communication streams comprises electronic communications through the communication device; and
an application configured to initiate a loopback mode of operation of the communication device;
wherein during the loopback mode of operation, the one or more communication streams are suspended.

16. The computer system of claim 15, wherein during suspension of a first communication stream, an application corresponding to the first communication stream continues to execute.

17. The computer system of claim 15, wherein:
the device driver is configured to maintain a device information data structure corresponding to the communication device;
the device information data structure includes a representation of each of the one or more communication streams; and
the one or more communication streams are suspended by modifying the representations of the one or more communication streams.

18. The computer system of claim 15, wherein the device driver is configured to drop a communication from a first communication stream if the communication is received while the communication stream is suspended.
